(19) United States
(12) Patent Application Publication
(10) Pub. No.: US 2014/0151813 A1
(43) Pub. Date: Jun. 5, 2014

(54) COMPUTER CHIP ARCHITECTURE

(71) Applicant: Alexandros Cavgalar, Wichita, KS (US)

(72) Inventor: Alexandros Cavgalar, Wichita, KS (US)

(21) Appl. No.: 13/690,761

(22) Filed: Nov. 30, 2012

(51) Int. Cl. H01L 27/092

(52) U.S. Cl. CPC H01L 27/092
USPC 257/369

(57) ABSTRACT

A computer chip utilizing a hybrid metal gate wherein metal inserted poly silicon (MIPS) is used for nMOS and replacement metal gate (RMG) is used for pMOS, and wherein poly silicon doping over metal gates has been performed. The chip may be bombarded with boron isotopes or may have impurities added to dampen ringing noises. The chip may comprise a constituent material having characteristics of venting wells and distributed connections between layers. A highly reflective, stable metalloid agent may be bound to deposited metal layers. The constituent material may comprise a crystal having natural vacant states. The computer chip may comprise vertically stacked transistors. Vertical surface cavities located at metal junction points may serve as exhaust pipes.

### CROSS-REFERENCE TO RELATED APPLICATION

This application claims the benefit of U.S. Provisional Application No. 61/565,473, filed Nov. 30, 2011.

### BACKGROUND OF INVENTION

This application relates to computer chip architecture, especially for use in a networked system and in particular gateway devices, systems and methods.

### SUMMARY

It is becoming increasingly common for homes, businesses, etc. to have access to a wide variety of networked or remote services. Illustrative services include Internet service, cellular voice and data services, on-line services, phone services (PSTN, POTS, VoIP, etc.), cable television services, satellite television services, satellite radio services, etc. Unfortunately, it is quite common for at least some of these services to each have their own access point as well as required hardware. As such, homes and businesses are frequently cluttered with numerous wires and cables as well as “electronically cluttered” with a variety of wireless access or communication points. Therefore, there exists a significant need for the ability to combine the access points to a significantly smaller number of access points as well as manage the communications between devices and networks.

Communications between devices and networks may be enhanced by a computer chip utilizing a hybrid metal gate wherein metal inserted poly silicon (MIPS) is used for nMOS and replacement metal gate (RMG) is used for pMOS, and wherein poly silicon doping over metal gates has been performed. The chip may be bombarded with boron isotopes or may have impurities added to dampen ringing noises. The chip may comprise a constituent material having characteristics of venting wells and distributed connections between layers. A highly reflective, stable metalloid agent may be bound to deposited metal layers. The constituent material may comprise a crystal having natural vacant states. The computer chip may comprise vertically stacked transistors. Vertical surface cavities located at metal junction points may serve as exhaust pipes.

### BRIEF DESCRIPTION OF THE DRAWINGS

The drawings, when considered in connection with the following description, are presented for the purpose of facilitating an understanding of the subject matter sought to be protected.

FIG. 1 is a first illustrative system.

FIG. 2 is a second illustrative system.

FIG. 3 is a third illustrative system.

FIG. 4 is a fourth illustrative system.

FIG. 5 is a fifth illustrative system.

FIG. 6 is a sixth illustrative system.

FIG. 7 is an illustrative gateway device.

FIG. 8 is an illustrative method for transferring calls between a gateway device and a telecommunications network.

FIG. 9 is an illustrative method for communicating caller ID information.

FIG. 10 is an illustrative method for providing on-demand services.

FIG. 11 is an illustrative method for providing dynamic control of streamed content.

FIG. 12 is an illustrative method for providing parental controls.

FIG. 13 is an illustrative method for providing text messages.

FIG. 14 is a schematic of a particular embodiment of a chip architecture of the present application.

FIG. 15 is an electron micrograph showing the vertical view of a heavy isotope bombarded lowest metal run.

FIG. 16 is an electron micrograph showing a particular embodiment of a chip architecture of the present application.

FIG. 17 is an electron micrograph showing a particular embodiment of a chip architecture of the present application.

FIG. 18 is a representation of three dimensional communication connections within the novel computer chip.

### DETAILED DESCRIPTION

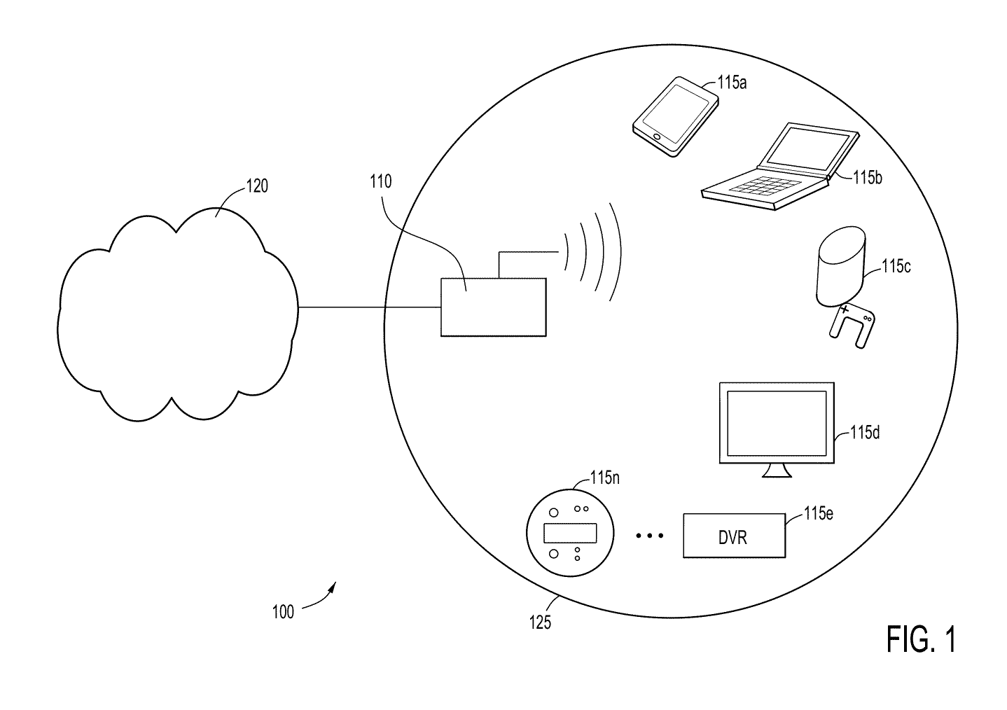

Referring now to the FIGS. wherein like elements are referred to with the same numerals throughout and wherein FIG. 1 illustrates a system 100 in accordance with the present disclosure. The system 100 includes a gateway device 110, one or more terminals 115a-115n (collectively 115), and an external network 120.

The external network 120 may include any number of networks capable of providing communications to and/or receiving communications from the gateway device 110. For example, the external network may be one or more, or any combination of, wireless networks, data or packet networks, publicly switched telephone networks (PSTN), cellular networks, wide area networks (WAN), adjacent local area networks (LAN), etc. In one embodiment, the external network 120 includes the Internet.

The participant terminals 115 may include any suitable device operable to act as a client on a network. Illustrative terminals 115 include, but are not limited to, personal computers, desktop computers, laptop computers, tablet computers, video game systems, servers, any suitable telecommunications device, including, but not limited to, VoIP telephones, smart telephones or wireless devices, such as cellular telephones, personal digital assistants (PDA), communications enabled mp3 players, etc., smart meters, closed circuit television systems, communications enabled televisions, DVRs, set top boxes, satellite radio receivers, printers, copiers, switches, enterprise switches, network access storage (NAS), or any other device suitable to act as a terminal on the local network. The terminals 115 may communicate with the gateway 110 using wireless communications or hardwired connections, such as fiber optics, cable, DSL, telephone lines, and other similar connections.

As will be further discussed below, the gateway device 110 and terminals 115 form a local area network (LAN) 125 such that the gateway device 110 manages communications between the external network 120 and LAN 125. Further, the gateway device 110 is configured to provide communications between and otherwise manage or control communications between the terminals 115 and the external network 120.

The gateway device 110 includes a plurality of communications modules to communicate with one or more of the external network 120 and terminal(s) 115. In one embodiment, the gateway device 110 includes a first communication module configured to communicate with the external network 120. Illustrative first communications modules, include without limitation, a WAN communications module (e.g. any DocSIS, DSL, xDSL, ADSL, ADSL 2, ADSL 2+, VDSL, VDSL2, SHDSL, GbE, ONT, GPON ONT, SPON ONT, EPON ONT, BPON ONT, MoCA, TDM, any T-carrier, any E-carrier, any J-carrier, etc.), a WLAN communications module, an Ethernet communications module, or any other suitable communications module. Additionally, it will be appreciated that the term “module” should be understood broadly so as to encompass any device for communicating with an external network including, but not limited to one or any combination of modems, peripheral cards, modules, on-chip arrangements, transmitters, receivers, transreceivers, etc.

The gateway device 110 further includes one or more communications modules for communicating with one or more terminals 115. The second, third, fourth, etc. communications module(s) for communicating with one or more terminals 115 may include, without limitation, a voice gateway communications module, an Ethernet communications module, a VoIP communications module, a Femto communications module, a Zigbee communications module, a WiFi communications module, WHDMI communications module, print servers, DVR communications module, etc. In one embodiment, one or more of the communications modules is a wireless USB-based communications module (e.g. a wireless WHDMI USB module, etc.). It will be appreciated that any communications module, or any number or combination of communications modules, configured to communicate with one or more terminals may be employed and remain within the scope of the present disclosure.

Suitable illustrative communications modules for communicating with the external network 120 and/or terminals 115 of the system include, without limitation: the PacketAMC board offered by ADAX, Inc.; any of the AMC modules (AM4500, AM4510, AM4520, etc.) offered by Kontron AG; the iSPAN 3639 T1/E1 controller offered by Interphase Corp.; the ETRX3 Zigbee module offered by Telegesis Ltd.; the XB24-Z7PIT-004 module offered by Digi International, Inc.; the Femtocell SoC solution offered by Freescale Semiconductor Inc.; and the Starcore Voice Gateway offered by Freescale Semiconductor Inc. However, it will be appreciated that any suitable device for providing communication between the gateway device 110 and the external network 120 and/or terminals 115 may be employed as any suitable communication module in the system.

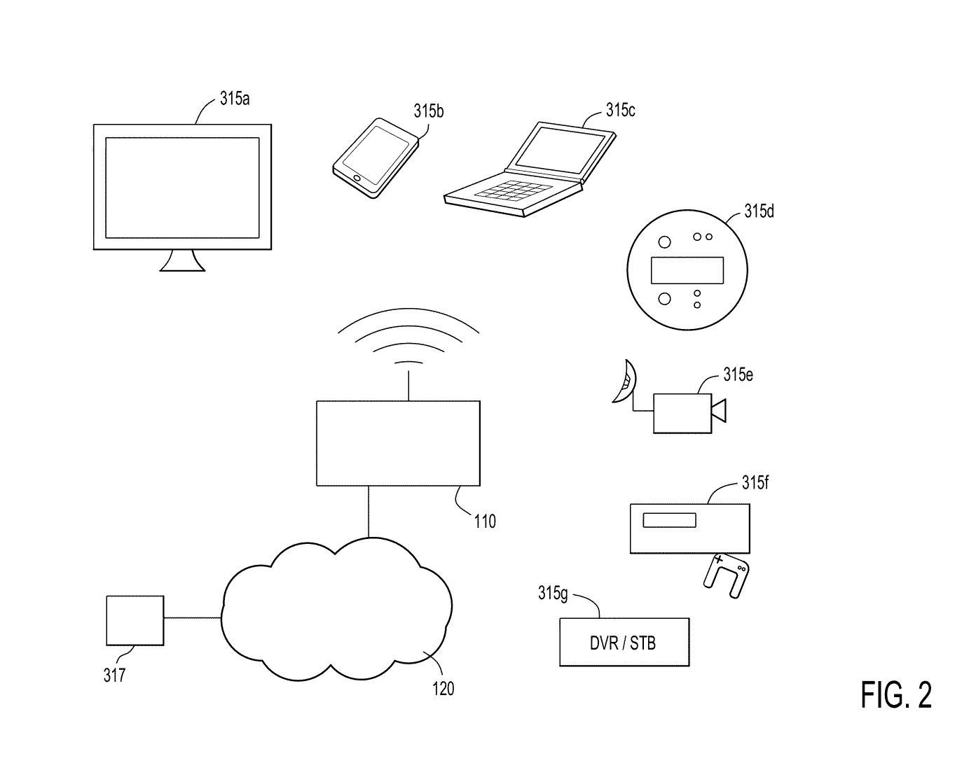

FIGS. 2-6 illustrate several non-limiting examples of the implementation of the system of the present disclosure. It will be appreciated that the following illustrative embodiments are not intended to limit the scope of the disclosure in any way. Each of the illustrative embodiments in FIGS. 2-6 illustrate a variety of terminals in several different settings. It will be appreciated that embodiments having a plurality of the same terminal type are expressly contemplated. Additionally, it will be appreciated that additional terminal types not shown may be employed, including but not limited to the various terminals mentioned above. Also, fewer terminals than shown may be employed and that the expression of one terminal type is not at the exclusion of all other terminal types. Also, it will be appreciated that the functionality of the gateway device 110 in one embodiment may be employed in every other embodiment and it will be appreciated that expression of only a certain functionality in one embodiment is not at the exclusion of all other the functionality described in other embodiments herein.

FIG. 2 illustrates the implementation of the gateway device 110 as a home communication and entertainment gateway. In this embodiment, the terminals (collectively 315) include a television 315a, a mobile device 315b, a computer 315c, a smart meter 315d, a security system 315e, a gaming system 315f and a DVR/STB 315g. The gateway device 110 manages communications between the terminals 315 and external network 120. For example, the gateway device 110 may permit access to the external network 120 by one or more of the terminals 315—this may include, without limitation, providing communications between one or more of the terminals and the external network 120 by transferring data between the terminals 315 and network 120, which may include converting the data so that it is usable by the terminals 315 or endpoint in the external network 120, etc. For example, and without limitation, the gateway device 110 may act so as to permit one of the terminals to access the Internet, etc. Additionally, the gateway device 110 may manage communications between the terminals 315. For example, and without limitation, the gateway device 110 may receive a command from one terminal and pass the command to a second terminal such that the second terminal is responsive to the command from the first terminal (e.g. a record command from the mobile device 315b or computer 315c to the DVR/STB 315g, etc.). Furthermore, the gateway device 110 may manage remote access to one of the terminals 315 over the external network 120. For example, and without limitation, a remote device 317 (e.g. mobile device, computer, etc.) may be permitted to access one of the terminals 315 so as to allow control of the terminal (e.g. remote access to control a smart meter 315d, security system 315e, DVR/STB 315g, etc.).

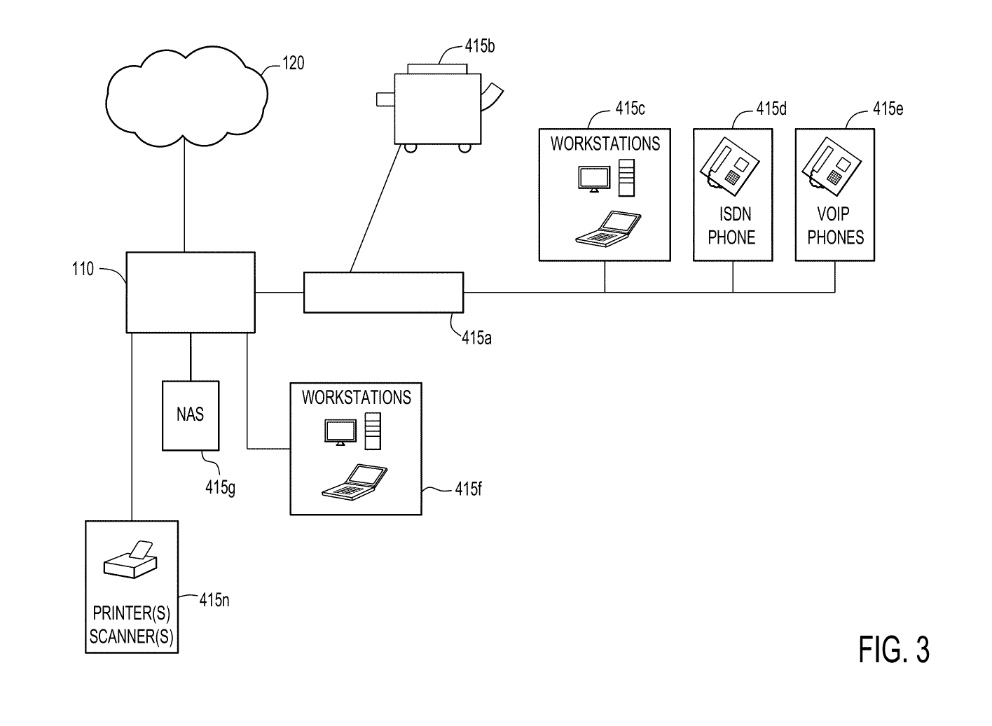

FIG. 3 illustrates the implementation of the gateway device 110 in an office setting. The gateway device 110 may be configured to serve as a small home office gateway, a multi-service business gateway or any other suitable gateway or device. In this embodiment, the terminals (collectively 415) include a switch 415a, such as an enterprise switch, which is connected to devices such as a multifunction device (copier/scanner/printer) 415b, workstations 415c, phones such as ISDN lines 415d or VoIP lines 415e. It will be appreciated that in some instances a switch may not be desirable or necessary and that a switch 415a may not be employed and the terminals placed in direct communication with the gateway device 110. Further, even in instances where a switch 415a is employed, it may still be desirable for certain terminals to be in direct communication with the gateway 110 including, but not limited to, workstations 415f, network access storage (NAS) 415g, printers/scanners 415h, VoIP phone, any Power Over Ethernet (POE) enabled device, etc. The gateway device 110 may manage communications between the external network 120 and the terminals 415 as well as communications between terminals 415.

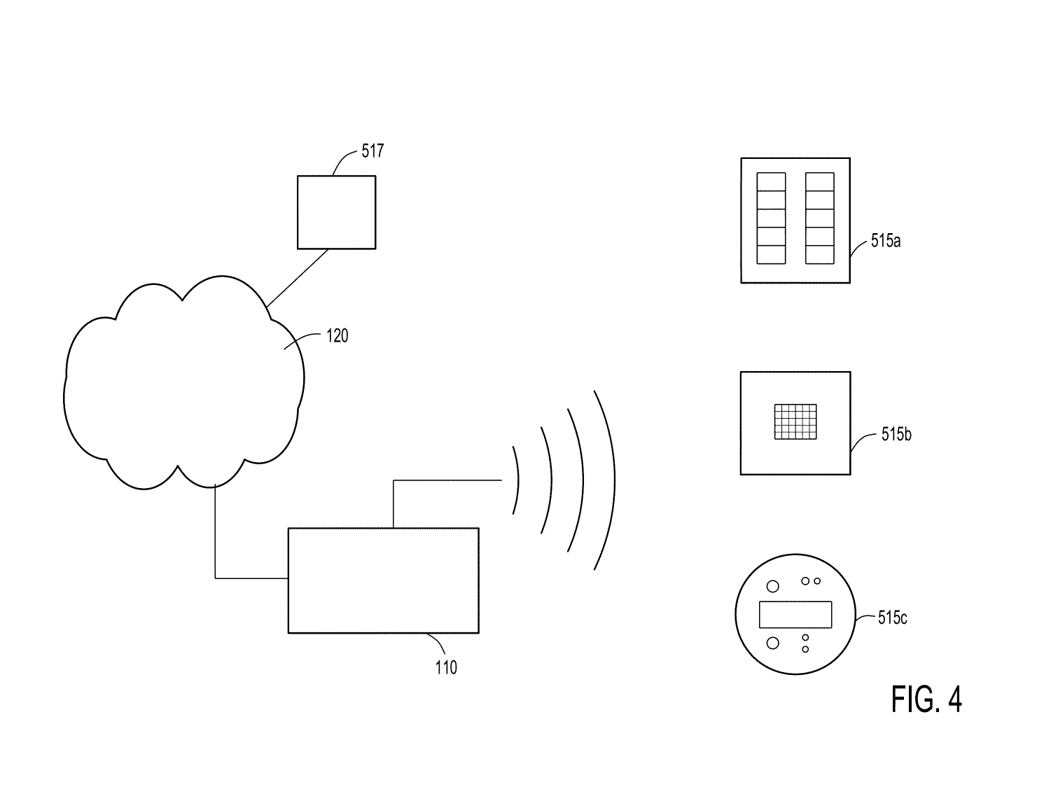

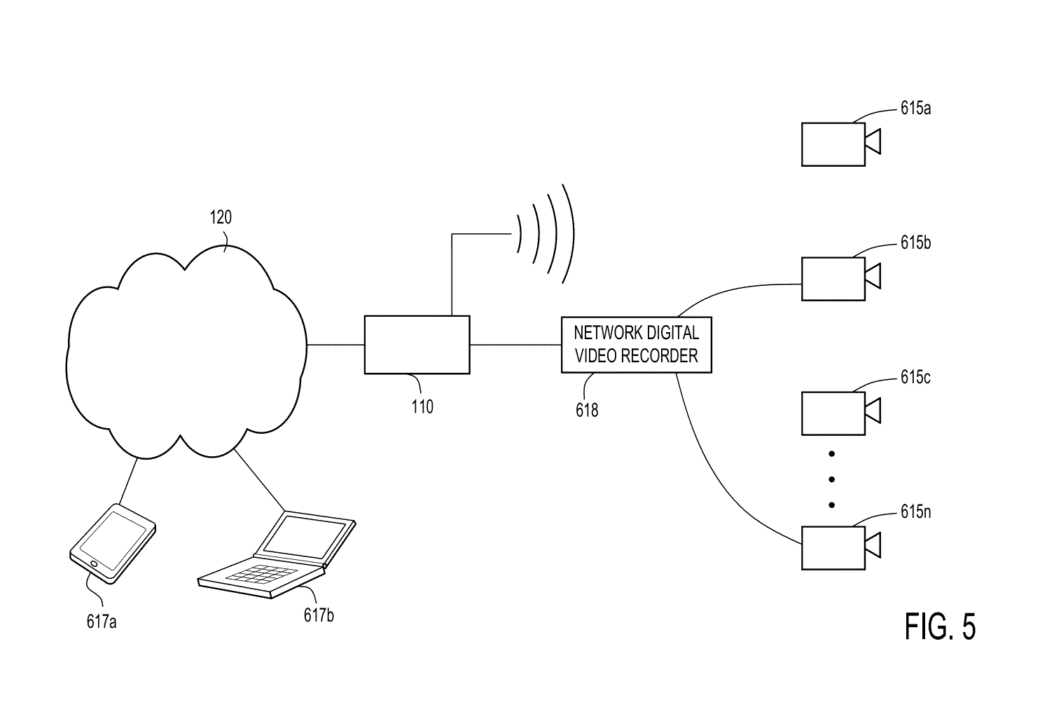

Referring now to FIG. 4, a gateway device 110 is shown in communication with smart meters (collectively 515). As used herein, the term smart meter refers to any device configured to monitor and/or control utilities, utility services, or the like. Illustrative smart meters include, without limitation, smart breaker boxes 515a, lighting control systems 515b, smart electric meters 515c, smart gas meters, smart water meters, industrial PLCs, access control systems, smart appliances, or any other suitable device or devices. In one embodiment, the gateway device 110 manages communications between one or more smart meters 515 such that the meter(s) 515 may be monitored or controlled by another terminal (not show in FIG. 5). Also, in one embodiment, the gateway device 110 may be configured to allow remote access to one or more smart meters 515 over the external network 120 such that a remote device 517 (e.g. mobile device, computer, etc.) may be permitted to access, monitor and/or control the smart meter(s) 515. It will be appreciated that the gateway device 110 provide smart meter management, including but not limited to energy grid management, for home area networks (HAN) as well as field area networks (FAN).

Referring now to FIG. 5, another embodiment employing the gateway device 110 is shown. In this embodiment, the terminals 615a-615n, collectively 615, include components for a closed-circuit television arrangement. In one embodiment, each of the terminals 615 is a camera such as a video camera, infrared camera, FLIR camera, thermographic camera, or any other device or devices suitable for a closed-circuit arrangement. In one embodiment, a terminal is a network digital video recorder 618 to which at least some of the cameras 615 are in communication with. Alternatively, if the gateway device includes persistent storage, the footage from the terminals may be stored thereon. In one embodiment, the gateway device 110 manages communications between other terminals (not shown) and the camera terminals 615 so that the other terminals are able to view, monitor and/or control the camera terminals 615 as well as view recorded footage from the cameras that is stored in the network digital video recorder 618 and/or persistent storage of the gateway device 110. Also, in one embodiment, the gateway device 110 may be configured to allow remote access to one or more of the terminals 615 and/or 618 over the external network 120 such that a remote device (e.g. mobile device 617a, computer 617b, etc.) may be permitted to view, monitor and/or control the camera terminals 615 as well as view recorded footage from the cameras that is stored in the network digital video recorder 618 and/or persistent storage of the gateway device 110. Further, in one embodiment, the gateway device may be configured to enhance the stored video footage so as to enhance the quality of the video or any other suitable aspect or characteristic of the video.

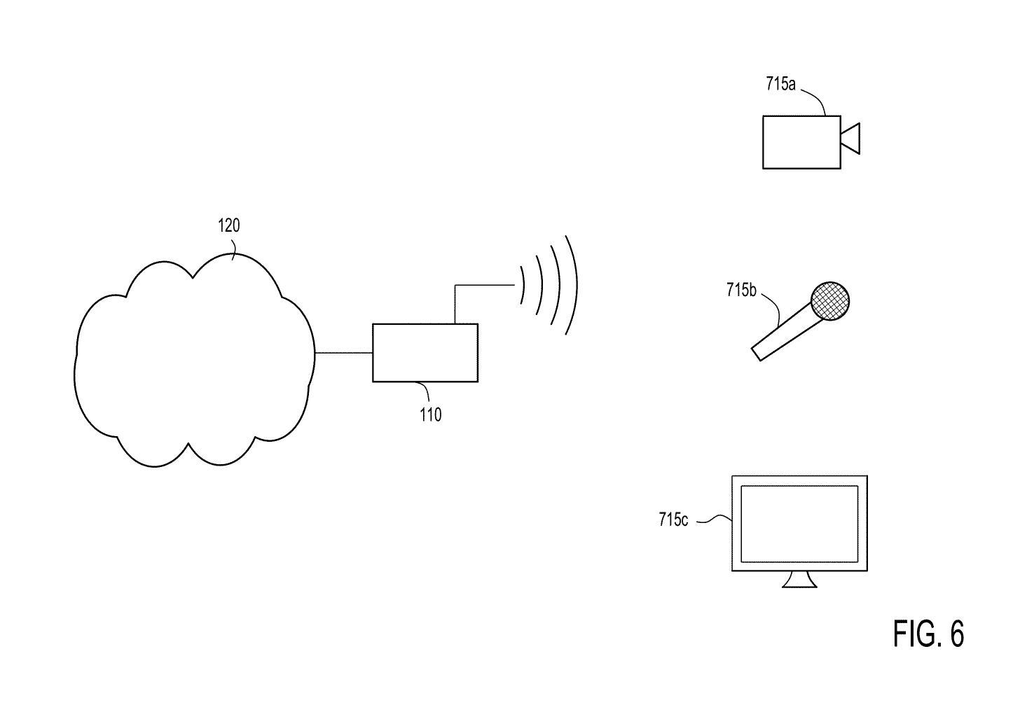

Referring now to FIG. 6, the gateway device 110 may be configured to also act as a unified communication controller. Here, the terminals (collectively 715) may include a video camera 715a, a microphone 715b, and a monitor or television 715c. The terminals may be discrete devices or combined in any suitable combination for an integrated device. The gateway device 110 may be configured to provide communications between each of the terminals 715 and the external network 120 such that the gateway device 110 is operable to provide real time video conferencing.

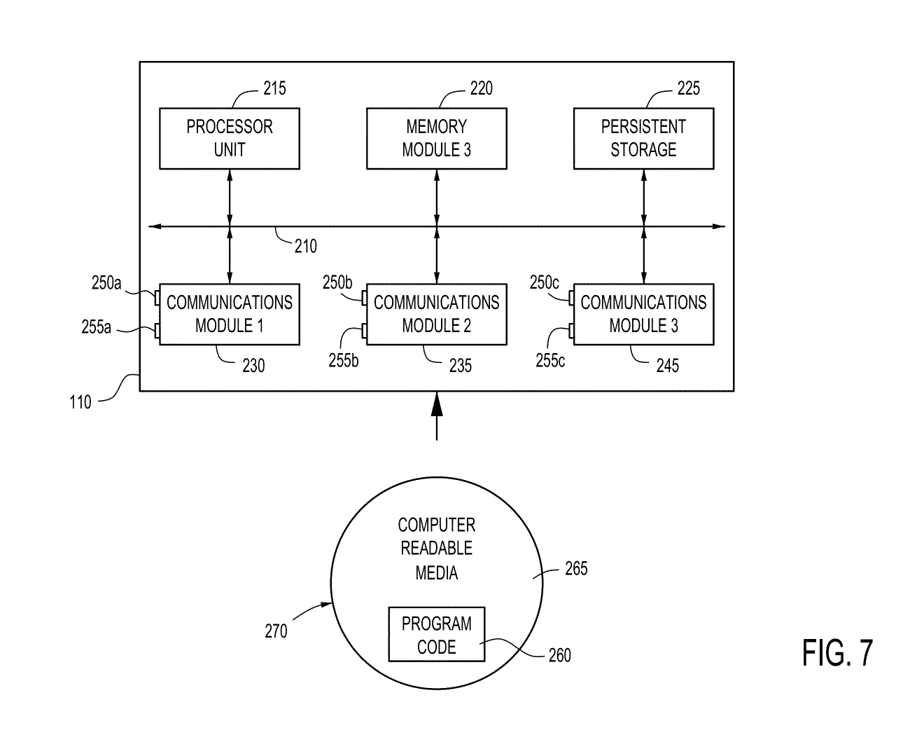

Referring to FIG. 7, a block diagram of a gateway device 110 is shown in which the illustrative embodiments may be implemented. Computer-usable program code or instructions implementing the processes used in the illustrative embodiments described herein, including all methods, may be located on the gateway device 110. The gateway device 110 includes a communications fabric 210, which provides communications between a processor unit 215, a memory 220, a persistent storage 225 the first communications module 230, second communications module 235 and third communications module 240. While three communications modules are shown herein, it will be appreciated that any number of communications modules may be employed and remain within the scope of the present disclosure. Further, it will be appreciated that in some embodiments the gateway device 110 may not include a persistent storage 225.

The processor unit 215 serves to execute instructions for software that may be loaded into the memory 220. The processor unit 215 may be a set of one or more processors or may be a multi-processor core, depending on the particular implementation. Further, the processor unit 215 may be implemented using one or more heterogeneous processor systems in which a main processor is present with secondary processors on a single chip. As another illustrative example, the processor unit 215 may be a symmetric/asymmetric multi-processor system containing multiple processors of the same type.

The memory 220, in these examples, may be, for example, a random access memory or any other suitable volatile or non-volatile storage device. The persistent storage 225 may take various forms depending on the particular implementation. For example, the persistent storage 225 may contain one or more components or devices. For example, the persistent storage 225 may be a hard drive, a flash memory, a rewritable optical disk, a rewritable magnetic tape, or some combination of the above. The media used by the persistent storage 225 also may be removable. For example, a removable hard drive may be used for the persistent storage 225. In one embodiment, the persistent storage 225 also stores video data selectively stored by a user (e.g. as a DVR drive, etc.).

The communications modules 230, 235, 240 will be the communications modules as previously discussed—that is, at least one communications modules is configured to communicate with an external network and at least one module is configured to communicate with one or more terminals. Each module may take any of the forms previously discussed. In one embodiment, one or more of the communications modules includes an ingress connector 250a-250c (collectively 250) and an egress connector 255a-255c (collectively 255). The ingress connector 250 may be configured to test the incoming signal to the communications module without interruption. The egress connector 255 may be configured to test the outgoing signal from the communications module without interruption. Alternatively, an ingress connector and an egress connector may each be connected to the board of the gateway device 110 wherein the memory of the gateway device includes instructions that will allow the incoming and outgoing signals for each communications module to be tested via such connection to the gateway board. Thus, the line connections for each module may be tested.

Instructions for the operating system and applications or programs are located on the persistent storage 225. These instructions may be loaded into the memory 220 for execution by the processor unit 215. The processes or methods of the different embodiments may be performed by the processor unit 215 using computer-implemented instructions, which may be located in a memory, such as the memory 220. These instructions are referred to as program code, computer-usable program code, or computer-readable program code that may be read and executed by a processor in the processor unit 215. The program code in the different embodiments may be embodied on different physical or tangible computer-readable media, such as the memory 220 or the persistent storage 225.

In one embodiment, program code 260 is located in a functional form on a computer-readable media 265 and may be loaded onto or transferred to the gateway device 110 for execution by the processor unit 215. The program code 260 and the computer-readable media 265 form computer program product 270 in these examples.

In one example, the computer-readable media 265 may be in a tangible form, such as, for example, an optical or magnetic disc that is inserted or placed into a drive or other device that is part of the persistent storage 225 for transfer onto a storage device, such as a hard drive that is part of the persistent storage 225. In a tangible form, the computer-readable media 265 also may take the form of a persistent storage, such as a hard drive or a flash memory that is connected to the gateway device 110. The tangible form of the computer-readable media 265 is also referred to as computer recordable storage media.

Alternatively, the program code 260 may be transferred to the gateway device 110 from the computer-readable media 265 through a communication link to a communications module. The communication link or the connection may be physical or wireless in the illustrative examples. The computer-readable media 265 also may take the form of non-tangible media, such as communication links or wireless transmissions containing the program code 260. In one embodiment, the program code 260 is delivered to the gateway device 110 over the Internet.

The different components illustrated for the gateway device 110 are not meant to provide architectural limitations to the manner in which different embodiments may be implemented. The different illustrative embodiments may be implemented in a data processing system including components in addition to or in place of those illustrated for gateway device 110. Other components shown in FIG. 7 can be varied from the illustrative examples shown.

As one example, a storage device in the gateway device 110 is any hardware apparatus that may store data. The memory 220, the persistent storage 225, and the computer-readable media 265 are examples of storage devices in a tangible form.

In another example, a bus system may be used to implement the communications fabric 210 and may be comprised of one or more buses, such as a system bus or an input/output bus. Of course, the bus system may be implemented using any suitable type of architecture that provides for a transfer of data between different components or devices attached to the bus system. Further, a memory may be, for example, the memory 220 or a cache such as found in an interface and memory controller hub that may be present in the communications fabric 210. It will be appreciated that the communications fabric 210 may take any suitable form including, but not limited to, non-blocking switch fabric, non-blocking point-to-point/multi-point link or any other suitable communication fabric of communications path(s) between the various elements.

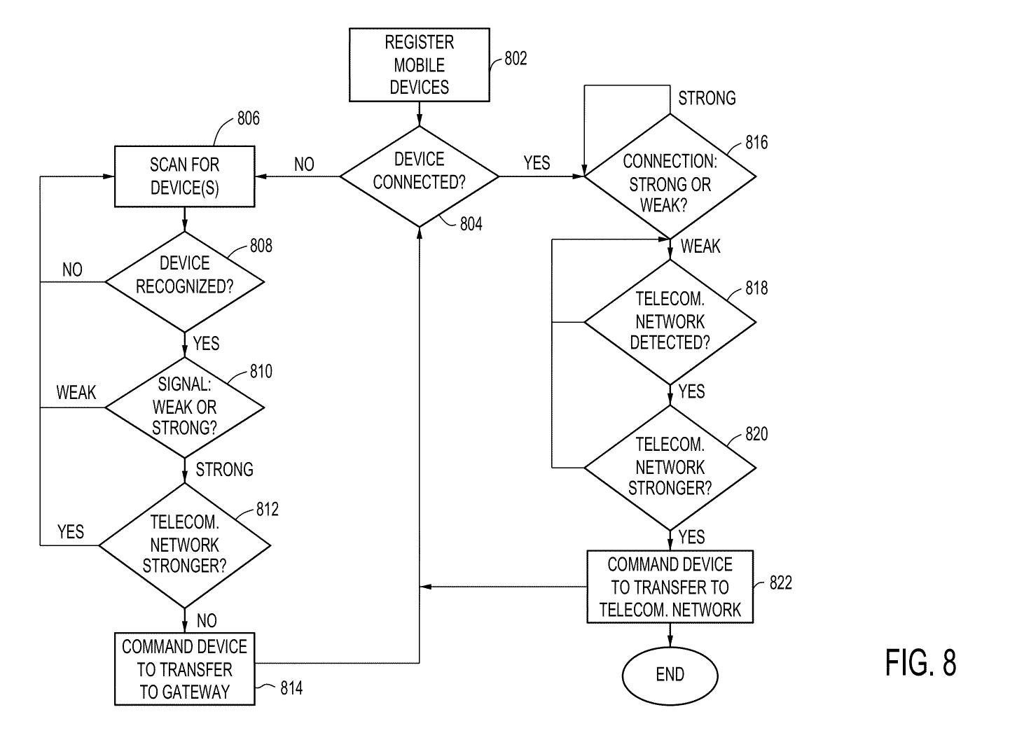

Referring now to FIGS. 8-13, illustrative methods of the gateway device 110 managing communications between the external network 120 and/or between the terminals are shown. It will be appreciated that the terms “managing” and “controlling” are to be understood broadly and encompass not only pushing communications through from the terminal(s) to one or both of another terminal and external network, and vice versa, but also converting data, providing security checks, storing data, caching data and any other means or method for optimizing said communications. Furthermore, while the following methods are discussed individually, it will be appreciated that a gateway device 110 may perform any of these methods, whether simultaneously, sequentially, selectively, user-selectively, etc., and remain within the scope of the present disclosure. Furthermore, the methods may also be employed by any device other than a gateway device as described herein and be considered within the scope of the present disclosure. Also, while the methods may sometimes refer to a single terminal, it will be appreciated that more than one terminal may be employed and remain within the scope of the present disclosure.

Referring now to FIG. 8, a method 800 for transferring calls between a telecommunications network and a gateway device is shown. As used herein, telecommunications network shall be understood broadly so as to encompass any network suitable for providing telecommunications, including but not limited to PSTN, POTS, cellular networks, wireless networks, data or packet networks, or any other suitable network. Further, it will be appreciated that the gateway device is in communications with an external network as described above, telecommunications or otherwise, such that a call may be transferred to or otherwise managed, handled or controlled by the gateway device. Also, the terms “strong,” “relatively strong,” “weak,” and “relatively weak” should be understood broadly so as to encompass a signal or output compared against a predetermined threshold value or a determination of the quality or strength of a signal based on the ability to maintain service within a predetermined quality range, or by any other suitable means or metric for ranking or otherwise determining the strength and/or quality of a signal.

First, a mobile device (also referred to as a terminal), e.g. cellular phones, etc., is registered with the gateway device [step 802]. This will permit the gateway device to only recognize or otherwise provide service to the mobile device registered therewith. Optionally, this step may include installing an application on the mobile device such that the mobile device provides the necessary information to the gateway device (e.g. tower strength, signal strength of telecommunications network, etc.) and/or is responsive to commands from the gateway device (e.g. handover command, etc.), but it will be appreciated that such an application may not always be desirable or necessary.

Once the mobile device(s) have been registered, the gateway device is configured to scan or otherwise recognize mobile devices that become within range of the gateway device [step 804]. In one embodiment, a WiFi and/or a Femto module of the gateway device is employed for scanning or otherwise recognizing mobile devices within range. However, it will be appreciated that any suitable module or device may be used for this purpose. If it is determined that a mobile device is not connected, the gateway will remain in a stand-by mode with respect to this method and/or continue to scan for mobile devices [step 806]. Once a mobile device is detected, the gateway device will determine if the mobile device is recognized as a device having been previously registered with the gateway device [step 808]. In an alternative embodiment where the mobile device is configured to provide an initial communication to a recognized gateway, this step may be optional or not included in the method. If the mobile device is not recognized, the gateway device continues to scan for a recognized mobile device or, alternatively, awaits an initial communication from a previously registered mobile device [step 806]

If the mobile device is recognized by the gateway as a registered mobile device, the gateway device will determine the strength of the signal or communications between the mobile device and the gateway device [step 812]. If the signal is relatively weak, the gateway device may be configured to return to any of the previous steps (e.g. steps 804-810). If the signal is relatively strong, the gateway device will query the mobile device to determine the strength of the signal between the mobile device and the telecommunications network [step 812]. In one embodiment, the mobile device is queried for the relative signal strength between the mobile device and a cellular tower the mobile device is connected to. However, it will be appreciated that the mobile device may be queried about the signal strength between the mobile device and any telecommunications network and remain within the scope of the present disclosure. If the signal strength associated the telecommunications network is stronger than the signal strength between the mobile device and the gateway device, the gateway device may be configured to return to any of the previous step (e.g. steps 804-812).

If the signal strength between the mobile device and the gateway device is stronger, the gateway device will, if necessary, make the necessary connection via the external network such that the call maybe transferred from the telecommunications network to the gateway device without interruption. The gateway device may then command the mobile device to transfer the call to the gateway device [step 814].

The gateway device may further be configured to handover a call from a mobile device in communication with the gateway device to a telecommunications network. If a mobile device is connected to the gateway device [step 804], the gateway device will monitor the signal strength and determine if the signal strength is relatively strong or relatively weak [step 816]. If the signal is relatively strong, the gateway device will maintain the connection and continuously or periodically monitor the signal strength. If the signal strength is relatively weak, the gateway device will determine if a telecommunications network is within range [step 818]. This may be accomplished by the gateway itself or by querying the mobile device to determine if the mobile device detects a telecommunications network. If no telecommunications network is detected, the gateway may be configured to return to any of the previous steps (e.g. steps 804-815).

If a telecommunications network is detected, the gateway device may determine whether the signal or connection with the gateway device is stronger than the signal to the telecommunications network [step 820]. If the signal to the gateway device is stronger, the gateway device may maintain the connection and may be further configured to return to one of the forgoing steps (e.g. steps 804-820). If the signal to the telecommunications network is stronger, the gateway device may command the mobile device to initiate a handover sequence, as is known in the art, so that the call may be transferred from the gateway device to the telecommunications network [step 822]. The method may then be concluded and/or return to step 804.

The forgoing method may be employed in a variety of contexts. In one embodiment, the mobile device is a cellular phone and the telecommunications network is a cellular network whereby the gateway device may transfer a call to or from the telecommunications network to an external network in communication with the gateway device (e.g. PSTN, POTS, VoIP, etc.). In another embodiment, rather than a call being transferred, the connection for streaming data (e.g. YouTube, Hulu, Netflix, etc.) may be transferred (e.g. between a 3G or 4G telecommunications network and an internet connection managed or maintained by the gateway device, etc.).

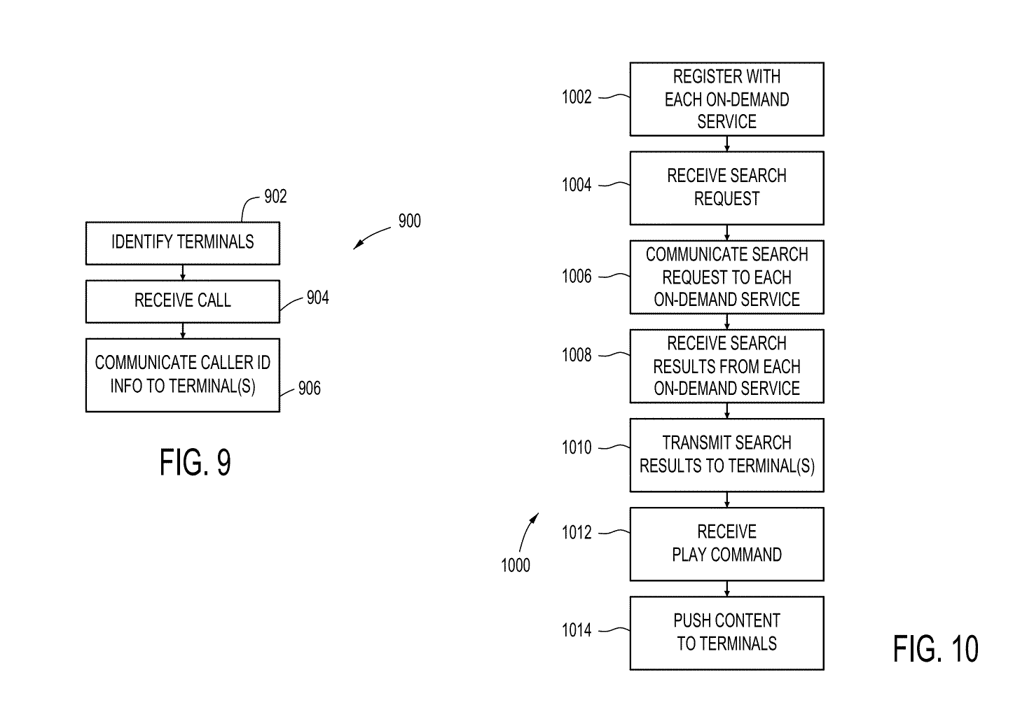

Referring now to FIG. 9, a method 900 for providing caller ID information to one or more terminals is shown. First, one or more terminals are designated to receive caller ID information when an incoming call is received by the gateway device from an external network [step 902]. Next, a call is received wherein the call has caller ID information associated therewith [step 904]. In response thereto, the gateway device communicates the caller ID information to the previously designated devices [step 906].

Referring now to FIG. 10, a method 100 for providing on-demand services to one or more terminals is shown. On-demand services shall be understood to include any service for providing content via an external network to a user or users. Illustrative content includes video, audio, or any other suitable content. Illustrative on-demand service providers include, without limitation, Hulu®, YouTube®, Netflix®, Pandora®, Songza® and the like. First, the registration information for each on-demand service is entered and stored in the gateway device [step 1002]. A search request from at least one terminal may then be received [step 1004]. The search request may then be communicated to each on-demand service via the external network [step 1006]. The search results from each on-demand service may then be received [step 1008]. The search results may then be communicated to one or more terminal(s) [step 1010]. A command, such as play, download, etc., from a terminal may then be received [step 1012]. The gateway device may then push or stream the on-demand content to one or more terminals [step 1014]. It will be appreciated that the gateway device may stream/push the content to the terminal(s) as it is received from the on-demand service, may cache a suitable amount of the content prior to streaming/pushing the content to the terminal(s), store the content in persistent storage and transmit/push the content to the terminal(s) at a later time, etc.

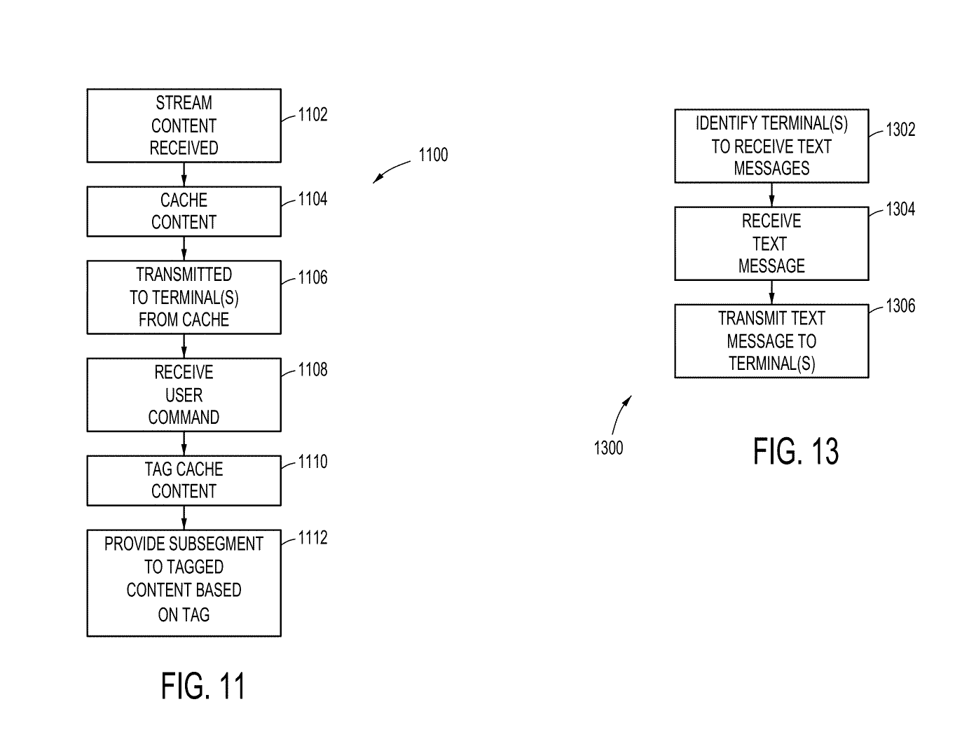

Referring now to FIG. 11, a method 1100 of providing dynamic control of streamed content is provided. First, the gateway device streams content [step 1102]. The content may be streamed from an on-demand source via the external network, from persistent storage, or from any other suitable source (e.g. HD television signal via antenna, etc.). The gateway device will stream the content to a cache, located in memory, persistent storage or other suitable repository, so as to buffer the streaming content [step 1104]. The buffered content may then be pushed or otherwise communicated to one or more terminals [step 1106]. The gateway device may then receive a user command [step 1108]. Illustrative user commands here include, without limitation, pause, record, etc. Upon receiving the user command, the cached content will be tagged in accordance with the user command [step 1110]. The gateway device may later provide access to the tagged content based on the tag [step 1112]. For example, and without limitation, content in cache may be tagged with a pause tag whereby a user may later access the paused content in cache and even from a terminal different than the terminal from which the pause command was made. In another example without limitation, cached content having a record tag may be transferred to persistent storage for subsequent access by the user and even from a terminal different than the terminal from which the record command was made.

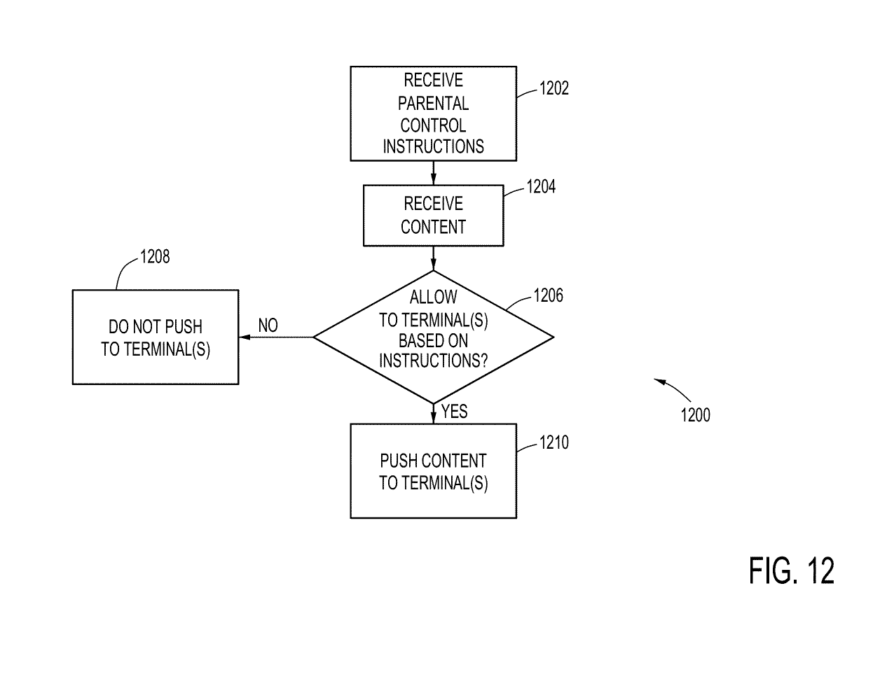

Referring now to FIG. 12 a method 1200 for providing parental control is shown. First, the gateway device receives parental control instructions [step 1202]. The parental control instructions may include restrictions based on any suitable content rating systems, restrictions based on channel, restrictions based on time, or any suitable combination thereof. In one embodiment, the restrictions may also be limited to certain terminal(s) and are not applied equally to all terminal(s). The gateway device may then receive content to be transmitted or pushed to one or more terminals [step 1204]. This content may be received in response to a specific command (e.g. to stream/play from a particular external network source, stream/play from persistent storage, etc.) or may be more passive in nature (e.g. channel surfing by a user). The gateway device may then determine if the content is permitted by the terminal(s) according to the parental control instructions [step 1206]. If the content is not permitted to the terminal(s), the gateway device will not stream/push the content to the terminal(s) [step 1208]. If the content is permitted to the terminals, the gateway device will stream/push the content to the terminal(s) [step 1210]. It will be appreciated that this method may be applied to any suitable content type including, but not limited to, video, audio, Internet content etc.

Referring now to FIG. 13, a method 1300 of delivering text messages is shown. First, terminal(s) for receiving text messages are identified to the gateway [step 1302]. The gateway may then receive a text message from a source via the external network [step 1304]. The gateway device may then transmit/push the text message to the previously identified terminal(s). In one non-limiting example, a terminal for receiving text messages may be a DECT phone.

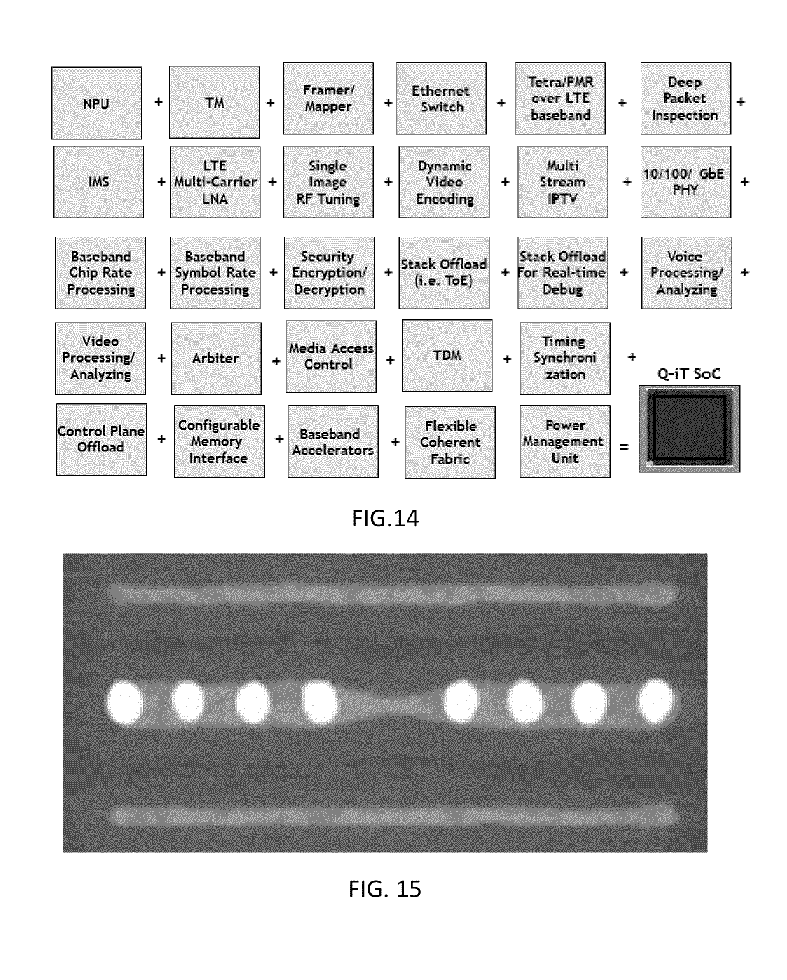

The systems described above may be realized more effectively by utilizing computer chips having the schematic architecture as shown in FIG. 14 and which can provide the following improvements.

One of the improvements utilizes a Hybrid Metal Gate (HMG) concept. With HMG constructions, the chips may utilize Metal Inserted Poly Silicon (MIPS) for nMOS and Replacement Metal Gate (RMG) for pMOS. More reliable 11 baseband block operation may be achieved by using pMOS V_{T} at EOT.

Regarding both MIPS and RMG, actual Poly Silicon doping over metal gates is performed. It is noted that when heavily doped poly silicon with highly charged electrons are deposited during vertical build with high phonon energy parameters, any incoming wavelengths may be blocked by increasing refraction angle, thus causing much wider reflection parameters. Should the refraction angle need to be reduced, the chip may be bombarded with boron isotopes to reduce energy levels. This generates both reduced refraction angles and also potential glow in metal lines of short extent. Decay in the energy scattering will diminish rapidly but can still generate sufficient charge to view the metal runs of the transistors.

A glow occurs at individual fuse points after heavy bombardment of metal layers, which may be seen through an electron microscope. See FIG. 15. Excitation density may be controlled by applying various powers or levels of boron radiation. The resultant quantum leap then generates the fluorescence. However, when additional isotopes are not present, the energy will be emitted as two photons, as quantum leap to ground stage will occur as two events, thus causing large refraction angles. This may cause faulty gate count.

Ringing noises, especially under low power switching conditions, may be eliminated by adding impurities to dampen the noise. During both ion implementation and oxide regrowth special diffusion patterns may be added on the gate surroundings. Because in the MIPS process the gate is completely isolated, diffused channels are kept level at the gate height. In the RMG process, the initial so-called “dummy” gates may be removed and actual metal electrodes may be added at the end.

However, this may possibly increase overall process complexity. This complexity increases exponentially when going from a single dimensional (1-D) design approach to a three dimensional (3-D) design approach. Therefore, the RMG process fills in the diffusion points as does the MIPS process. This additional barrier reduces ringing noises.

However, eliminating diffusion points by leveling leaves less room for thin cap insertion. Hence, locations where thin caps are to be installed may be reduced or limited. The extra dampening layers having only limited area used for thin caps create concentrated heat flow points, which in turn increases the sintering temperature.

In an intrinsic semiconductor the number of electrons is equal to the number of holes. Thermal excitation of an electron leaves behind a hole in the valence band. This is reflected in an equation:

nᵢ=pᵢ=2(k_{B}T/2π²)^{3/2}(mₑmₕ)^{3/4}e^{(-Eg/2kBT)}

In the above equation, nᵢ is intrinsic electron concentration; pᵢ is hole concentration; K is Boltzmann's constant (8.6 E-5 eV/K); T is temperature in degrees Kelvin; and E_{g} is bandgap. This is part of the Fermi-Dirac distribution principle that describes semiconductor materials' behavior.

Based on the above stated principle, the dopant concentration for both isolation material and also the construction metal materials will contain normalized electron and hole parameter, reflected in the equation:

σ=(nₑμₑ+pₑμₕ)

In the above equation, μₑ & μₕ are particle drifting parameters, or alternatively stated, electron mobility; nₑ & pₑ are population density parameters; and σ is material conductivity.

Creating dopant density may be described by the equation:

n≅√(nₒN_{d})*e^{(-Ed/2kBT)}

In the above equation, n₀ is electron concentration; N_{d} is effective density state of the dopant material; and e^{(-Ed/2kBT)} is Boltzmann distribution of the dopant.

The above two equations allow control of the density of both the layer isolation material and also the metals. during actual gate construction the layer isolation variable particle acceleration method may be utilized to control dopant and host material concentrations.

Using Schrodinger's equation and the behavior of wave particle, movement can be analyzed using the following equation:

εₖ=−α−2γ(cos kₓa+cos k_{y}a+cos k_{z}a)

In the above equation, Eₖ is energy of a particular particle at an excited stage, and α & γ represent particle's excitation level. By controlling the particle's direction and the speed, different lattice creation can result.

Momentum and average position of particles may be calculated to normalize the wave function that can allow quantification of the particle's overall energy, the following equation may be utilized:

ψₖ(r)=√N*Σⱼe^{(ik.rj)}φ(r−rj)

In the above equation, ψₖ(r) is the overall density wave function, and φ is the space derivative of the continuous wave function (a.k.a. product parameter). This enables calculation of potential quantum well function using the following equation:

ψₖ=e^{(ik.r)}u₀(r)

and also the density wave function, which will be used to control the particle's energy in the trapped well and the density distribution in the later stages.

The above equations enable control of the lattice behavior of a crystal, which will in turn enable construction of a material having “venting” wells and distributed connections between layers, and hence a natural contiguous lattice construction.

If during the construction of each metal layer, a highly reflective, stable metalloid agent such as boron or boronase may be used that can be bound to the deposited metal layer and highly excited. This can impact the reflection and refraction parameters of the incident wave, creating polarization-like parameters and/or change of the angles. In turn, isolation of the metal layer may be generated.

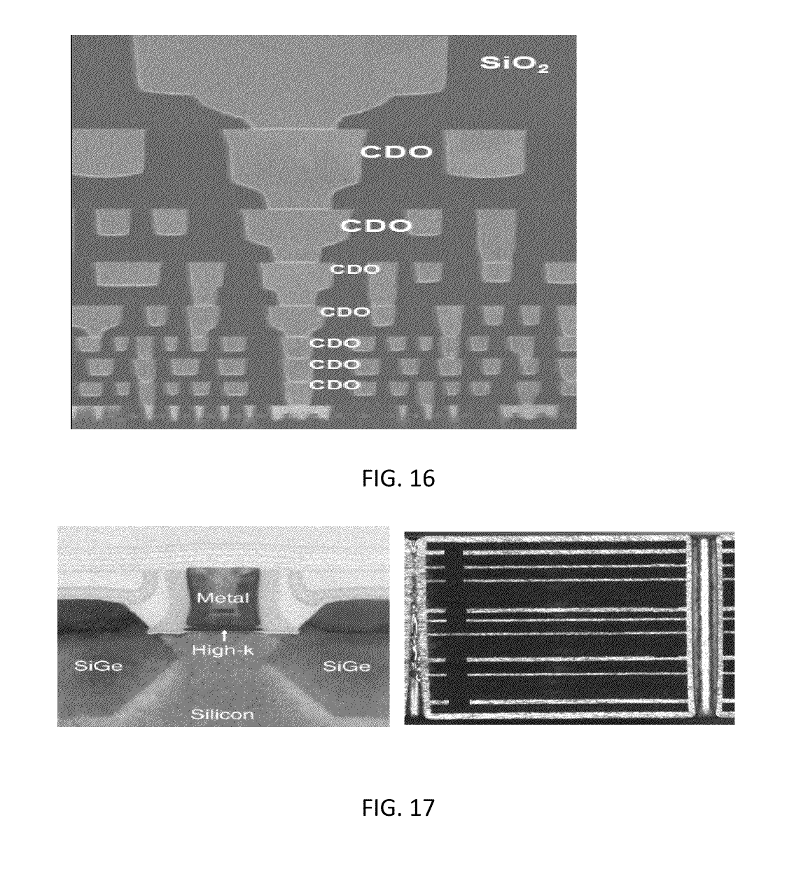

Utilizing the above equations and the principles embodied thereby, a crystal having many natural vacant states may result. Superior vertical bonding at the transistor edges may be generated by utilizing the lowest energy surface. See FIG. 16

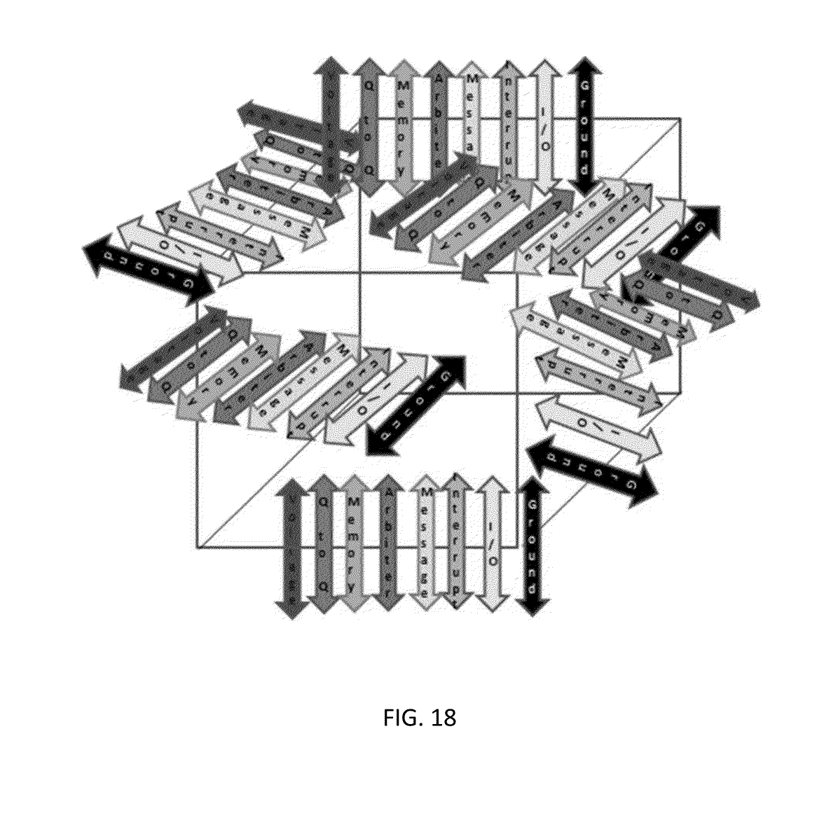

Thus, by creating vertically stacked transistors we can create vertical surface cavities at the metal junction points, which acts as exhaust pipes for the entire metal run. However, this will require side-step connection to the vias. Although the side-step connection is more complex, since via connections will create bonding points, via connection entries can be used as C4 bumps to substrate. See FIG. 17.

Macro blocks may be connected with mesh type architecture as shown in FIG. 14. But unlike two dimensional schemes, the resultant connection may have additional non-blocking 3-D fabric connections. As seen in FIG. 18, different levels of memory such as L1, L2 cache, input queue, output queue, packet memory, table memory, etc., may be separated. Each general block may be triggered as a Task Optimized Processor (TOP) and can execute any given speed. Use of multi-gate transistor technology may be utilized to achieve trigger effect between cores, macro blocks, and arbiters.

While the present disclosure has been described in connection with what is considered the most practical and preferred embodiment, it is understood that this disclosure is not limited to the disclosed embodiments, but is intended to cover various arrangements included within the spirit and scope of the broadest interpretation so as to encompass all such modifications and equivalent arrangements. Also, as used herein, including in the claims, the terms first, second, third, etc . . . used in relation to an element are for reference or identification purposes only, and these terms, unless otherwise indicated, are not intended to describe or suggest a number, order, source, purpose, or substantive quality for any element for which such a term is used.

1. A computer chip utilizing a hybrid metal gate wherein metal inserted poly silicon (MIPS) is used for nMOS and replacement metal gate (RMG) is used for pMOS.

2. The computer chip of claim 1, wherein poly silicon doping over metal gates has been performed.

3. The computer chip of claim 1, wherein the chip has been bombarded with boron isotopes.

4. The computer chip of claim 1, wherein impurities have been added to dampen ringing noises.

5. The computer chip of claim 1, comprising a material having venting wells and distributed connections between layers.

6. The computer chip of claim 1, further comprising a highly reflective, stable metalloid agent bound to deposited metal layers.

7. The computer chip of claim 1, comprising a constituent material which further comprises a crystal having natural vacant states.

8. The computer chip of claim 1, comprising vertically stacked transistors, and wherein vertical surface cavities located at metal junction points may serve as exhaust pipes.
